(19) United States
(12) Patent Application Publication
(10) Pub. No.: US 2008/0023694 A1
(43) Pub. Date: Jan. 31, 2008

(54) Display device and method of manufacturing the same

(75) Inventors: Seok-Woon Lee, Tainan (TW); Sung-Soo Park, Tainan (TW); Biing-Seng Wu, Tainan City (TW)

Correspondence Address: RABIN & Berdo, PC, 1101 14TH STREET, NW, SUITE 500, WASHINGTON, DC, 20005, US

(73) Assignees: CHI MEI EL Corp.; CHI MEI OPTOELECTRONICS CORP.

(21) Appl. No.: 11/492,080

(22) Filed: Jul. 25, 2006

(51) Int. Cl. H01L 29/08; H01L 35/24; H01L 51/00

(52) U.S. Cl. 257/40

(57) ABSTRACT

A display device and a method of manufacturing the same are provided. The display device comprises a substrate, a light-emitting element and a switch element. The substrate has a substrate upper surface and a recess region lower than the substrate upper surface. The light-emitting element comprises a first electrode, a light-emitting layer and a second electrode. The first electrode is disposed on the recess region. The light-emitting layer is disposed on the first electrode. The second electrode is disposed on the light-emitting layer. The switch element is disposed on the substrate upper surface and electrically connected to the light-emitting element.

### BACKGROUND OF THE INVENTION

1. Field of the Invention

The invention relates in general to a display device and a method of manufacturing the same, and more particularly to a light-emitting display device and a method of manufacturing the same.

2. Description of the Related Art

An organic light-emitting display device, which is a self-emissive device advantageously has the properties of being driven by a low DC voltage, high luminance, high efficiency, high contrast, light weight, thin thickness, and flexibility, and thus becomes a mainstream in a next generation of flat panel displays.

FIG. 1 is a schematic illustration showing a conventional organic light-emitting display device 100. The organic light-emitting display device 100 includes sub-pixels 110 arranged in a matrix. Each sub-pixel 110 includes a switch element 120 and a light-emitting element 130. The switch element 120 is typically a thin film transistor (TFT) for driving the light-emitting element, and the light-emitting element 130 is typically an organic light emitting diode (OLED). The switch element 120 includes a gate electrode 121, a source/drain 122. The light-emitting element 130 includes a first electrode 131, a second electrode 132 and a light-emitting layer 133. Wherein the light-emitting layer 133 has a multi-layer structure of organic thin films. The first electrode 131 is disposed on the insulating layer 111 and in the contact hole 111a to electrically connect the light-emitting element 130 to the switch element 120. The switch element 120 provides a driving voltage or current to the light-emitting element 130 and controls the light-emitting element 130 to emit light.

The processes of manufacturing the display device 100 are mainly divided into a process of manufacturing the switch element 120 and a process of manufacturing the light-emitting element 130 according to the above-mentioned two elements.

FIG. 2A˜2C is a schematic illustration showing a defect in the process of the conventional display device 100. Firstly refer to FIG. 2A, a substrate 140 having a substrate upper surface 140a is provided. Next refer to FIG. 2B, a switch element comprising a gate electrode 121 and two source/drain 122 is formed. In the process of manufacturing the switch element 120, particles 191 are unavoidably produced in the films. Afterward refer to FIG. 2C, a light-emitting element 130 comprising a first electrode 131, a light-emitting layer 133 and a second electrode 132 is formed. Wherein the first electrode 131 is disposed in the contact hole 111a for electrically connecting the light-emitting element 130 and the switch element 120. When the particles 191 are disposed in the light-emitting region A130, the first electrode 131 and the second electrode 132 may be short-circuited due to the projection which formed by particle 191.

FIG. 3 is a schematic illustration showing another defect of the conventional display device 100. Because the trend of the display device is to build logic circuits and memory circuits in a display substrate, a low temperature poly silicon (LTPS) manufacturing process has been developed under the consideration of the demands on the heat-resisting limitation of the substrate, high integration and high carrier mobility. The poly crystallization methods of the LTPS manufacturing process mainly includes an excimer laser annealing (ELA) process or a metal induced crystallization (MIC). In addition to the problem of the particles 191 generated in the manufacturing processes, the display device 100 applying the LTPS manufacturing process further encounters the problem of the residue of active layer 124. With regard to the excimer laser annealing method, the process of the crystallization of the active layer 124, a part of the grain at the grain boundary may ridged and pressed due to the grain growth of itself and neighboring grains. Thus, an unsmooth surface 150 of the buffer layer 141 owing to active layer residue which formed after etching the active layer 124 at grain boundary due to thicker film thickness or roughness on top of buffer layer 141. In addition, with regard to the metal induced crystallization method, nickel di-silicide (NiSi₂) trapped at grain boundary and due to the lower etching rate compares with poly silicon, the unsmooth surface 150 are formed. The same with abovementioned particle defects, after the subsequent evaporating process of the light-emitting element 130 is finished, the first electrode 131 and the second electrode 132 will be short-circuited due to the projections.

As mentioned hereinabove, either the poly silicon or the amorphous silicon process may encounter the problem of the particle generation in the manufacturing processes of the display device. The low temperature poly silicon manufacturing process may further cause the problem of the unsmooth surface 150 of the buffer layer 141. Thus, a new display device structure is provided to prevent the above-mentioned problems.

### SUMMARY OF THE INVENTION

It is therefore an object of the invention to provide a display device and a method of manufacturing the same, wherein a film stacked in a light-emitting region of a sub-pixel is removed, a recess region lower than a substrate upper surface is formed, or a part of a first electrode is configured to contact the substrate and be lower than the substrate upper surface. Thus, in-film particles deposited in the film and the unsmooth surface can be completely removed according to the above-mentioned method. The spirit of the invention is the formation of recess region just before the formation of the first electrode. Accordingly, the problems of the particles and the unsmooth surface can be overcome, the yield rate can be improved, and the manufacturing cost can be reduced.

The invention achieves the above-identified object by providing a display device comprising a substrate, a light-emitting element and a switch element. The substrate has a substrate upper surface and a recess region lower than the substrate upper surface. The light-emitting element includes a first electrode, a light-emitting layer and a second electrode. The first electrode is disposed on the recess region. The light-emitting layer is disposed on the first electrode. The second electrode is disposed on the light-emitting layer. The switch element is disposed on the substrate upper surface and electrically connected to the light-emitting element.

The invention also achieves the above-identified object by providing a display device including a substrate and a plurality of sub-pixel. The substrate has a substrate upper surface. The plurality of sub-pixel includes a light-emitting element and a switch element. The light-emitting element includes a first electrode, a light-emitting layer and a second electrode. The first electrode has a first electrode bottom surface. The light-emitting layer is disposed on the first electrode. The second electrode is disposed on the light-emitting layer. The switch element is disposed on the substrate upper surface. The switch element is electrically connected to the light-emitting element. Wherein, a part of the first electrode bottom surface contacts the substrate and is lower than the substrate upper surface.

The invention also achieves the above-identified object by providing a method of manufacturing a display device, the method comprising the steps of: providing a substrate having an upper surface; forming a switch element on the substrate; forming a recess region on the substrate, wherein the recess region is lower than the upper surface; and forming a light-emitting element in the recess region, wherein the light-emitting element is electrically connected to the switch element.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 (Prior Art) is a schematic illustration showing a conventional organic light-emitting display device.

FIG. 2A˜2C (Prior Art) is a schematic illustration showing a defect in the process of the conventional display device.

FIG. 3 (Prior Art) is a schematic illustration showing another defect of the conventional display device.

FIG. 4 is a schematic illustration showing a display device according to the invention.

FIG. 5 is a flow chart showing a method of manufacturing the display device according to the invention.

FIGS. 6A to 6G are schematic illustrations showing steps of FIG. 5.

FIG. 7 is a schematic illustration showing a display device whose switch element if formed by amorphous silicon process according to the invention.

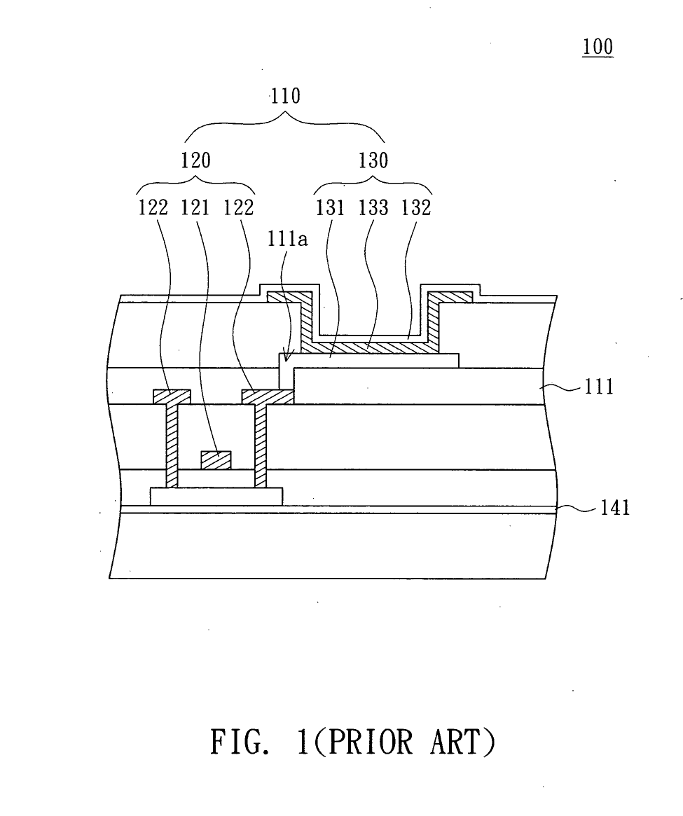

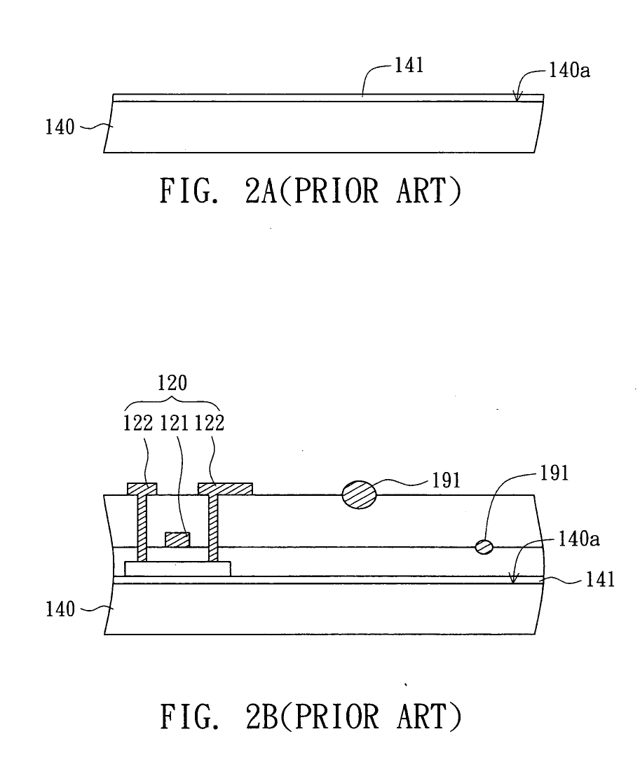

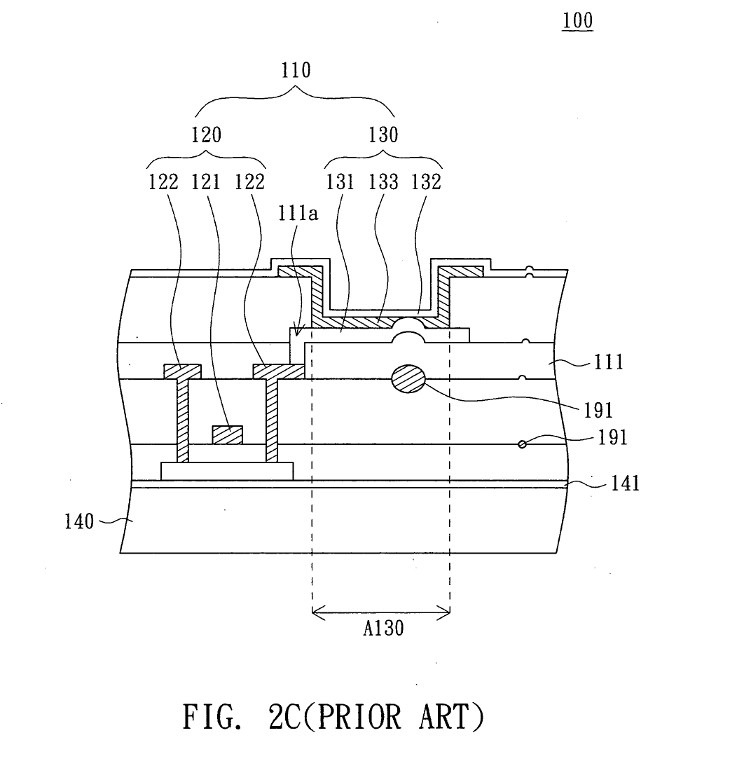

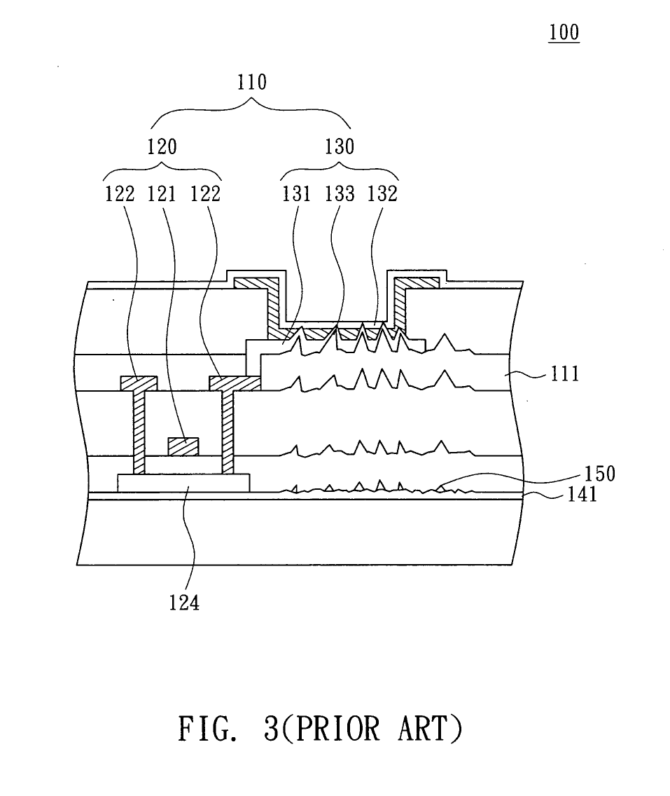

### DETAILED DESCRIPTION OF THE INVENTION

The invention provides a display device and a manufacturing process by removing the film stacked in the light-emitting region of a sub-pixel. The particles and the unsmooth surface encapsulated or deposited in the film are simultaneously removed by etching the stacked film. In order to remove the particles and the unsmooth surface completely, the substrate is over etched such that a part of the first electrode is disposed in a recess region of the substrate and the bottom surface of the first electrode is lower than the substrate upper surface. Thus, it is possible to ensure that the particles and the unsmooth surface can be removed completely. The display device and the method of manufacturing the same according to the invention will be described with reference to two preferred embodiments, which illustrate how the particles and the unsmooth surface are removed completely.

### First Embodiment

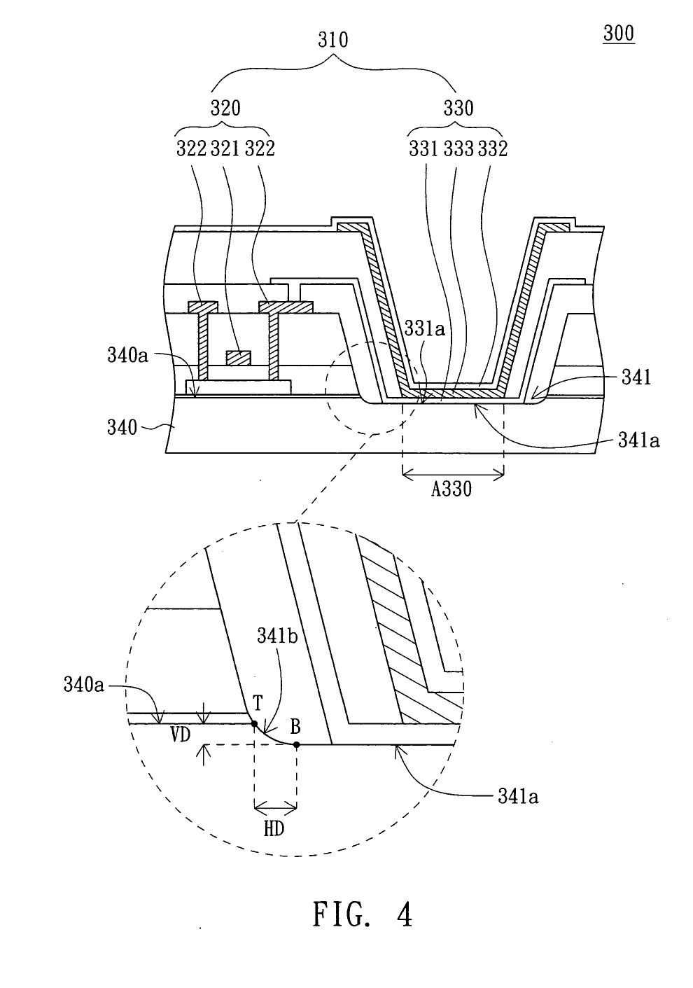

FIG. 4 is a schematic illustration showing a display device 300 according to the invention. Referring to FIG. 4, a display device 300 includes a substrate 340 and a plurality of sub-pixel 310. The substrate 340 has a substrate upper surface 340a. The sub-pixel 310 includes a light-emitting element 330 and a switch element 320. Herein, the structure of the sub-pixel 310 is illustrated by taking only one of the switch elements 320 and the light-emitting elements 330 as an example. The light-emitting element 330 includes a first electrode 331, a light-emitting layer 333 and a second electrode 332. The first electrode 331 has a first electrode bottom surface 331a. The light-emitting layer 333 is disposed on the first electrode 331. The second electrode 332 is disposed on the light-emitting layer 333. The switch element 320 is disposed on the substrate upper surface 340a, and the switch element 320 is electrically connected to the light-emitting element 330.

In the display device 300 of the invention, the substrate 340 further has a recess region 341, which is lower than the substrate upper surface 340a of the substrate 340. In addition, the first electrode 331 is disposed on the recess region 341. That is to say, the films on the substrate 340 in a light-emitting region A330 of the sub-pixel 310 is completely removed, such that a part of the first electrode bottom surface 331a is lower than the substrate upper surface 340a.

In this embodiment, the switch element 320 is a thin film transistor (TFT) and the light-emitting element 330 is an organic light emitting diode (OLED).

As shown in FIG. 4, the recess region 341 has the following features. The recess region 341 has a recess region bottom surface 341a and an inclined surface 341b, which inclines from the substrate upper surface 340a to the recess region bottom surface 341a. In addition, the inclined surface 341b has a top end T and a bottom end B, and a horizontal distance HD between the top end T and the bottom end B is greater than a vertical distance VD between the top end T and the bottom end B.

In addition, a cross-sectional profile of the above-mentioned inclined surface 341b is non-linear. As shown in FIG. 4, the cross-sectional profile is a curve.

In the method of manufacturing the display device according to the invention, how the structure of the display device 300 of FIG. 4 is formed and how the particles and the unsmooth surface encapsulated in the film are effectively removed will be described with reference to the following drawings.

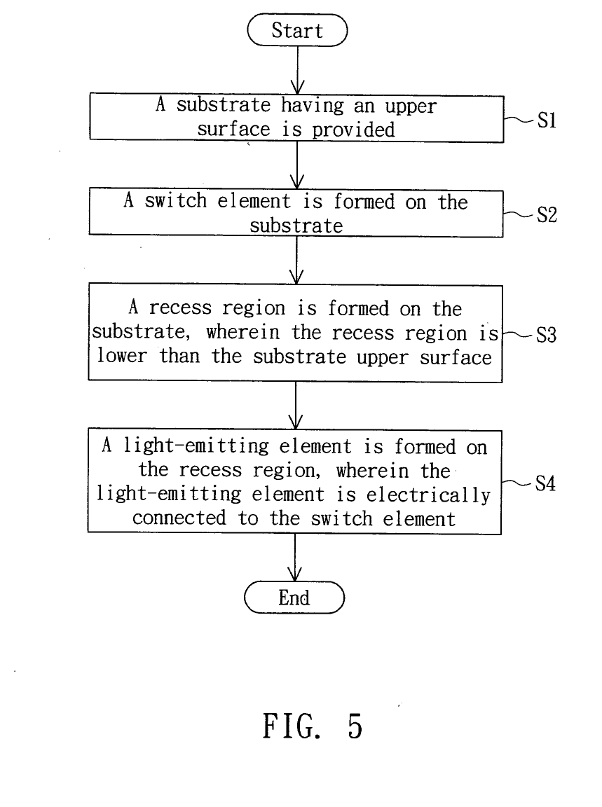

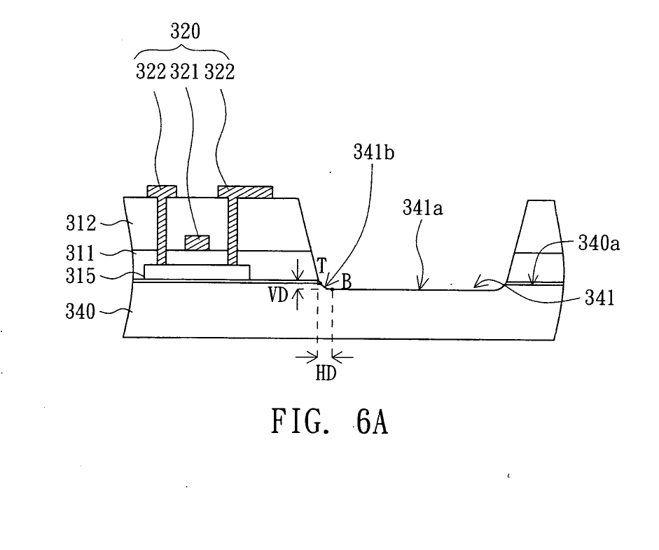

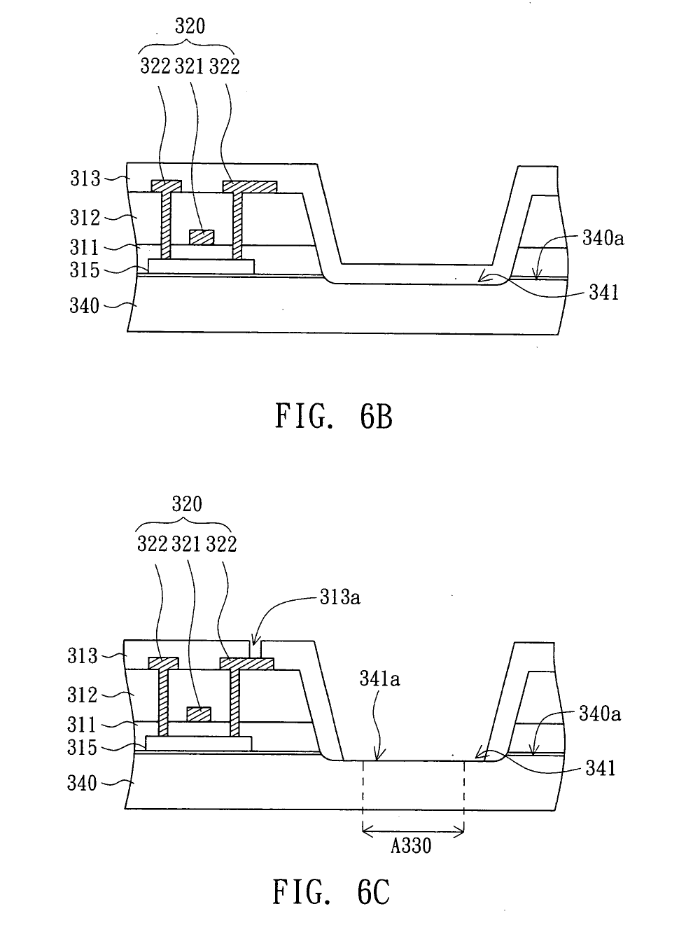

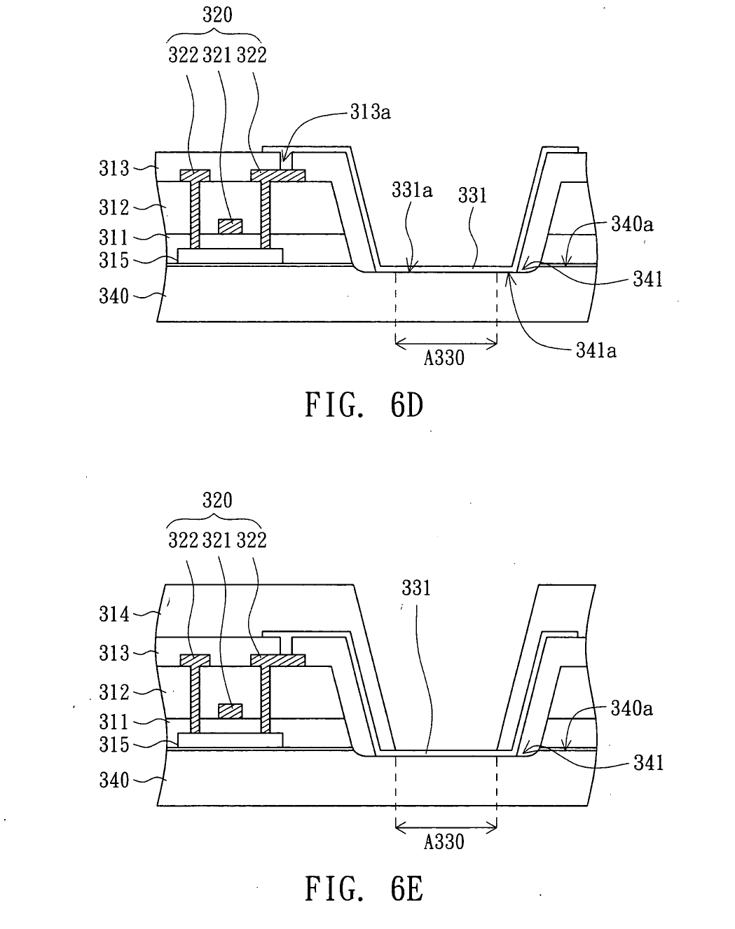

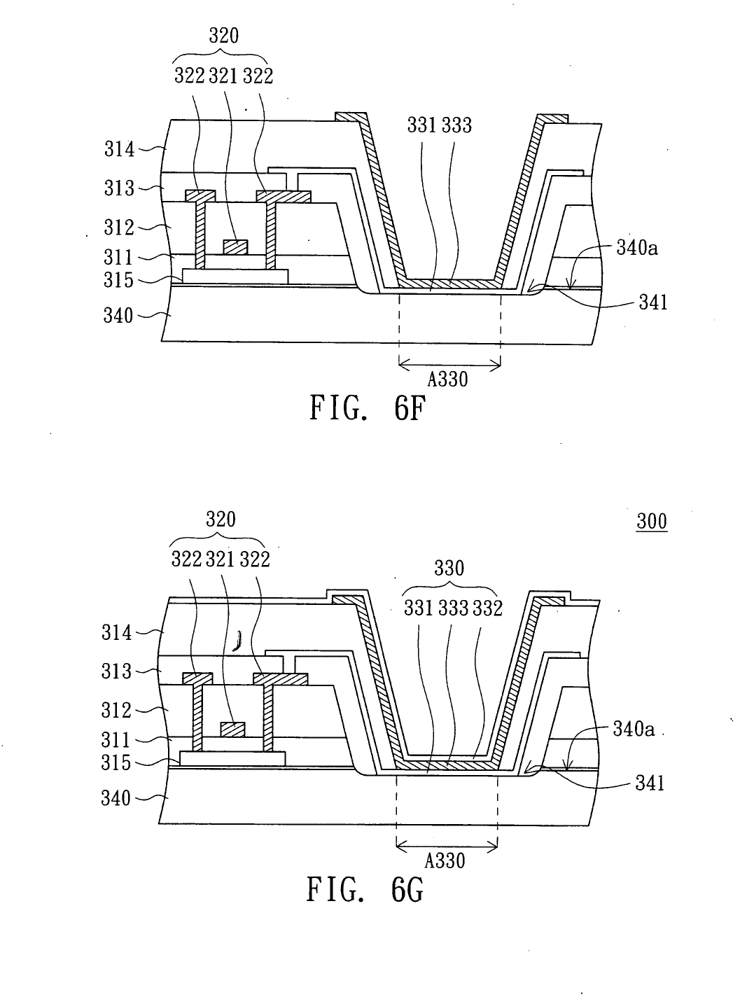

Please refer to FIGS. 5 and 6A to 6G. FIG. 5 is a flow chart showing a method of manufacturing the display device according to the invention. FIGS. 6A to 6G are schematic illustrations showing steps of FIG. 5. In step S1˜S3 of FIG. 5, please refer to FIG. 6A. Firstly a substrate 340 having a substrate upper surface 340a is provided. The substrate 340 may be a hard glass substrate or a flexible soft substrate. In this embodiment, the substrate 340 is a hard glass substrate, for example. Next, in step S2 of FIG. 5, a switch element 320 is formed on the substrate 340.

Next, in step S3 of FIG. 5, a recess region 341, which is lower than the substrate upper surface 340a, is formed on the substrate 340, as shown in FIG. 6A. The recess region 341 may be formed by way of wet etching, dry etching, dry plus wet etching, which combines the dry etching process with the wet etching process. Preferably, a better effect may be obtained using the wet etching process.

Preferably, the recess region 341 is formed by removing a 0.01-to-10 μm thickness of the substrate 340 downward from the substrate upper surface 340a. The downwardly removed thickness may be properly adjusted according to different processing parameters and the materials of the film and the particles.

In this step, removing the insulating layer 312, the insulating layer 311 and a part of the substrate 340 downward can remove the particles 191 interposed between the film layers. In addition, a clean recess region bottom surface 341a without any particle is left.

Then, in step S4 of FIG. 5, a light-emitting element 330 is formed in the recess region 341, as shown in FIGS. 6B to 6G. The light-emitting element 330 is electrically connected to the switch element 320. In FIG. 6B, an insulating layer 313 covering a source/drain connecting wiring 322 of switch element 320 as well as the recess region 341 is formed. Then, as shown in FIG. 6C, a contact hole 313a for exposing a part of the source/drain connecting wiring 322 is formed. Meanwhile, the insulating layer 313 of the recess region 341 is also exposed the recess region bottom surface 341a substantially corresponding the light-emitting region A330. Next, as shown in FIG. 6D, a first electrode 331 is formed on the recess region 341 and the contact hole 313a such that the first electrode bottom surface 331a contacts the substrate 340. In addition, the first electrode bottom surface 331a is lower than the substrate upper surface 340a by 0.01 to 10 μm. Heretofore, the first electrode 331 of the light-emitting element 330 is formed.

Next, as shown in FIG. 6E, an insulating layer 314 covering the switch element 320 and a part of the first electrode 331 is formed. The insulating layer 314 exposes the first electrode 331 of the light-emitting region A330. Then, as shown in FIG. 6F, a light-emitting layer 333 is formed on the first electrode 331. The contact portion between the light-emitting layer 333 and the first electrode 331 is located in the light-emitting region A330. Heretofore, the light-emitting layer 333 of the light-emitting element 330 is formed.

Then, as shown in FIG. 6G, a second electrode 332 is formed on the light-emitting layer 333. The second electrode 332 contacts the light-emitting layer 333 for forming the light-emitting element 330. Thus a display device 300 is constituted.

According to the method of manufacturing the display device 300, it is possible to effectively remove the particles deposited on the film in the light-emitting region A330.

### Second Embodiment

In addition, a display device whose switch is formed by a amorphous silicon process may also be applied in the invention. In the process of manufacturing the display device, which applies the amorphous silicon process, how to form the structure of the display device 300 of FIG. 4 and how to remove the unsmooth surface encapsulated in the film effectively. The structure of the display device whose switch element is formed by the amorphous silicon process will be described with reference to the following drawings.

The difference between the structure of the display device 400 in the second and the display device 300 in the first embodiments is the structure of the switch element 420, so detailed descriptions of the same processes will be omitted

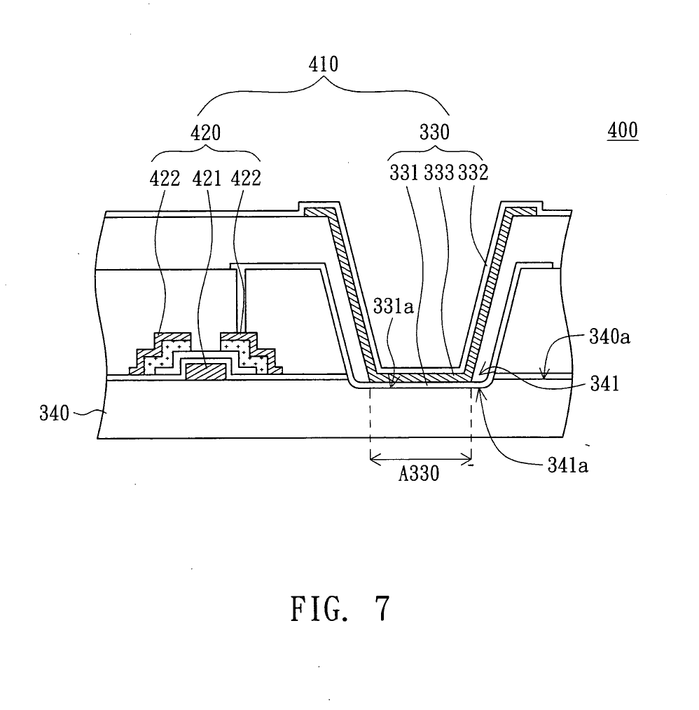

Please refer to FIG. 7. FIG. 7 is a schematic illustration showing a display device whose switch element if formed by amorphous silicon process according to the invention. The switch element 420 comprises a gate electrode 421 and two source/drain 422 is disposed on the substrate 340 and the switch element 320 is electrically connected to the light-emitting element 330. Wherein the switch element 420 which formed by the amorphous silicon process is a bottom-gate type structure, for example. In the display device 400 of the invention, the substrate 340 further has a recess region 341, which is lower than the substrate upper surface 340a of the substrate 340. In addition, the first electrode 331 is disposed on the recess region 341. That is to say, the films on the substrate 340 in a light-emitting region A330 of the sub-pixel 410 is completely removed, such that a part of the first electrode bottom surface 331a is lower than the substrate upper surface 340a.

In the display device and the method of manufacturing the same according to the embodiments, the film stacked in the light-emitting region of the sub-pixel is removed and a recess region lower than the substrate upper surface is formed, or a part of the first electrode is configured to directly contact the substrate and be lower than the substrate upper surface. Thus, the in-film particles or the unsmooth surface encapsulated in the film can be completely removed according to the above-mentioned method. Accordingly, the display device and the method of manufacturing the same according to the invention have the following advantages.

First, the particles encapsulated in the film layer and the unsmooth surface of the buffer layer on the substrate can be completely removed. No matter what the material of the particle is and the quantity of the unsmooth surface, removing the stacked film in the light-emitting region can completely remove the particles and the unsmooth surface encapsulated in the film layer.

Second, the yield can be greatly improved. The particles and the unsmooth surface encapsulated in the light-emitting region are always the main reason of producing the bad display device. This is because the short-circuited phenomenon between the first electrode and the second electrode caused by the protruding projection and the phenomenon of light scattering or light absorption owing to the above-mentioned defects have become a serious proof against the product quality. According to the display device and the method of manufacturing the same in this invention, the product yield can be greatly improved, and the stable quality of the product can be obtained.

Third, the manufacturing cost can be greatly reduced. The bad display device usually cannot be reworked, or wastes a lot of human works, materials and apparatus cost when it is reworked. According to the display device and the method of manufacturing the same in this invention, the product yield can be improved and the manufacturing cost can be reduced.

While the invention has been described by way of examples and in terms of referred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A display device, comprising:
a substrate having a substrate upper surface and a recess region lower than the substrate upper surface;
a light-emitting element, which comprises:
a first electrode disposed on the recess region;
a light-emitting layer disposed on the first electrode; and
a second electrode disposed on the light-emitting layer; and
a switch element, which is disposed on the substrate upper surface and electrically connected to the light-emitting element.

2. The display device according to claim 1, wherein the recess region has a recess region bottom surface and an inclined surface, which inclines from the substrate upper surface to the recess region bottom surface.

3. The display device according to claim 2, wherein the inclined surface has a top end and a bottom end, and a horizontal distance between the top end and the bottom end is greater than a vertical distance between the top end and the bottom end.

4. The display device according to claim 2, wherein a cross-sectional profile of the inclined surface is non-linear.

5. The display device according to claim 4, wherein the cross-sectional profile of the inclined surface is a curve.

6. The display device according to claim 1, wherein the switch element is a thin film transistor (TFT).

7. The display device according to claim 1, wherein the light-emitting element is an organic light emitting diode (OLED).

8. The display device according to claim 1, wherein the recess region is lower than the substrate upper surface by 0.01 μm to 10 μm.

9. A display device, comprising:
a substrate having a substrate upper surface; and
a plurality of sub-pixel, which each sub-pixel comprises:
a light-emitting element, which comprises:
a first electrode having a first electrode bottom surface;
a light-emitting layer disposed on the first electrode; and
a second electrode disposed on the light-emitting layer; and
a switch element, which is disposed on the substrate upper surface and electrically connected to the light-emitting element,
wherein a part of the first electrode bottom surface contacts the substrate and is lower than the substrate upper surface.

10. The display device according to claim 9, wherein the switch element is a thin film transistor (TFT).

11. The display device according to claim 9, wherein the light-emitting element is an organic light emitting diode (OLED).

12. The display device according to claim 9, wherein the first electrode bottom surface is lower than the substrate upper surface by 0.01 μm to 10 μm.

13. The display device according to claim 9, wherein the part of the first electrode bottom surface of the first electrode is disposed in a light-emitting region of the sub-pixel.

14. A method of manufacturing a display device, the method comprising the steps of:
providing a substrate having a substrate upper surface;
forming a switch element on the substrate;
forming a recess region on the substrate, wherein the recess region is lower than the substrate upper surface; and
forming a light-emitting element on the recess region, wherein the light-emitting element is electrically connected to the switch element.

15. The method according to claim 14, wherein the step of forming the light-emitting element comprises:
forming a first electrode on the recess region;
forming a light-emitting layer on the first electrode; and
forming a second electrode on the light-emitting layer.

16. The method according to claim 14, wherein the step of forming the switch element comprises:
forming a gate electrode;
forming a source/drain; and
forming a contact hole, which exposes a part of the source/drain, wherein the recess region and the contact hole are formed simultaneously.

17. The method according to claim 14, wherein the recess region is formed by way of wet etching.

18. The method according to claim 14, wherein the recess region is formed by way of dry plus wet etching.

19. The method according to claim 14, wherein the recess region is formed by removing a 0.01-to-10 μm thickness of the substrate downward from the substrate upper surface.

20. The method according to claim 14, wherein the switch element is formed by a low temperature poly silicon (LTPS) process.

21. The method according to claim 14, wherein the switch element is formed by an amorphous silicon process.
